(19) United States
(12) Patent Application Publication
(10) Pub. No.: US 2009/0256167 A1
(43) Pub. Date: Oct. 15, 2009

(54) LIGHT-EMITTING DEVICE

(75) Inventors: Martinus Petrus Joseph Peeters, Eindhoven (NL); Rene Jan Hendriks, Eindhoven (NL); Aldegonda Lucia Weijers, Eindhoven (NL); Claudia Mutter, Eindhoven (NL)

Correspondence Address: Philips Intellectual Property and Standards, P.O. Box 3001, Briarcliff Manor, NY, 10510-8001, US

(73) Assignee: KONINKLIJKE PHILIPS ELECTRONICS N.V., Eindhoven (NL)

(21) Appl. No.: 12/301,698

(22) PCT Filed: Jun. 4, 2007
(86) PCT No.: PCT/IB07/52089

§ 371 Date: Nov. 20, 2008

(30) Foreign Application Priority Data
Jun. 8, 2006 (EP) 06115111.4

(51) Int. Cl. H01L 33/00

(52) U.S. Cl. 257/98; 257/E33.067

(57) ABSTRACT

A light-emitting device (1) is disclosed, which comprises a radiation source (2), an inorganic layer (3) comprising a luminescent material (4); and a scattering layer (5) comprising scattering particles (6). The scattering layer (5) is located between the radiation source (2) and the inorganic layer (3), which is composed of a ceramic material.

### FIELD OF THE INVENTION

The present invention relates to a light-emitting device comprising a radiation source, an inorganic layer comprising a luminescent material, and a scattering layer comprising scattering particles. The scattering layer is located between said radiation source and said inorganic layer.

### BACKGROUND OF THE INVENTION

White light can, for example, be obtained by partial conversion of a blue light source, such as a LED (light-emitting diode), with a yellow phosphor. The blue light emitted by the LED excites the phosphor, causing it to emit yellow light. The blue light emitted by the LED is mixed with the yellow light emitted by the phosphor, and the viewer perceives the mixture of blue and yellow light as white light.

The LED emits blue light in an anisotropic fashion, i.e. the light is directionally dependent, and the phosphor emits light isotropically, i.e. in all directions. In the mixed light, the combination of the anisotropic light with the isotropic emission pattern results in an inhomogeneous distribution, usually visible as a blue ring in the emission.

By embedding the phosphor in a transparent phosphor body instead of using a strongly scattering phosphor powder layer, a considerable increase of the efficiency can be obtained. However, since only a part of the source light is converted by the phosphor body, a contribution of the source to the emission pattern is always present.

Correction can be performed by leaving some scattering in the phosphor body (not fully densified body material, leading to a translucent material) or by introducing some scattering in the encapsulant (or lens).

Controlling the porosity in the phosphor body in order to control the scattering will lead to thinner plates, which are more difficult to handle. Further, it is questionable whether the scattering properties can be reproducibly controlled.

Introducing some scattering in the encapsulant will scatter both the converted light and the source light, leading to a reduction of the efficacy gain. Moreover, scattering in the encapsulant will lead to a larger source, which is undesirable for many relevant applications. It is also not sure that in future products this encapsulant will still be used.

U.S. Pat. No. 6,791,259 discloses a white solid-state lamp with the aim of obtaining a homogenised light. The lamp of U.S. Pat. No. 6,791,259 comprises a radiation source, a luminescent material, and a radiation scattering material located between the radiation source and the luminescent material. The luminescent material comprises a packed phosphor particle layer or a dispersion of phosphor particles in a polymer encapsulating material, e.g. epoxy or silicone. Thus, the luminescent material is a strongly scattering layer, either in the form of phosphor particles only, or in the form of a dispersion of phosphor particles in an organic matrix. This strongly scattering layer leads to a low efficiency of the device, and a difficult control of the colour point of the device (a 1 μm variation on a total layer thickness of ˜10 μm leads to a significant change of the colour point).

There is thus a continuing need for a light-emitting device, in particular a phosphor converted LED, which does not suffer from the drawbacks of a non-homogenous light distribution, low efficiency, and/or a difficult colour point control.

### SUMMARY OF THE INVENTION

One aim of the present invention is to provide a light-emitting device, which overcomes the above-mentioned drawbacks of non-homogeneous light, low efficiency, and/or a difficult colour point control.

This aim is achieved by a light-emitting device comprising a radiation source; an inorganic layer comprising a luminescent material; and a scattering layer comprising scattering particles, which scattering layer is located between said radiation source and said inorganic layer, wherein the inorganic layer is composed of a ceramic material.

By a light-emitting device according to the invention, where a transparent or translucent ceramic body is glued to the led with a scattering optical bond, an emission pattern having surprisingly high homogeneity is obtained.

The scattering particles are preferably SiO₂ coated TiO₂ particles, and the scattering layer may comprise a silicone material. The scattering layer binds said inorganic layer to said radiation source, and could therefore be referred to as a scattering optical bond.

The ceramic material may be transparent. Alternatively, it may be translucent, e.g. due to Mie-scattering. The ceramic material may be in the form of a platelet. The radiation source may be a LED emitting blue light.

The luminescent material is preferably a phosphor emitting yellow light, e.g. cerium doped yttrium aluminium garnet, or manganese doped zinc sulphide.

The present invention also relates to a display device comprising a light-emitting device according to the above.

### BRIEF DESCRIPTION OF THE DRAWINGS

FIG. 1 represents a schematic side cross sectional view of a light-emitting device according to the invention.

### DESCRIPTION OF PREFERRED EMBODIMENTS

In the research work leading to the present invention, a way to avoid a non-homogeneous light distribution from a phosphor converted LED, while maintaining a high efficiency of the device, was surprisingly found.

The emission pattern of phosphor converted LEDs can contain a non-lambertian component from the LED, visible as a blue ring in the emission. This is an undesired characteristic of the device, since it impairs the performance of the device.

According to the present invention, this problem is overcome by incorporating the phosphors in a ceramic layer, and by introducing scattering particles in the optical bond between the LED and the ceramic layer.

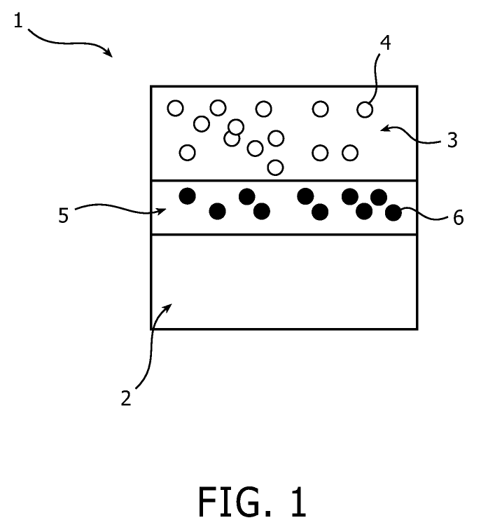

With reference to FIG. 1, a light-emitting device (1) according to the present invention comprises a radiation source (2), an inorganic layer (3) composed of a ceramic material and comprising a luminescent material (4), and a scattering layer (5) comprising scattering particles (6). The scattering layer (5) is located between the radiation source (2) and the inorganic layer (3).

By “composed of a ceramic layer” is meant that the inorganic layer essentially consists of a ceramic material. However, the inorganic layer “composed of a ceramic material” may nevertheless not be 100% ceramic due to e.g. impurities.

The radiation source is preferably a LED emitting blue light in the wavelength range of 420 to 490 nm. Several LEDs may also be used in a device according to the present invention.

The inorganic, ceramic layer is generally a self-supporting layer, preferably in the form of a platelet. However, other geometrical shapes of the ceramic layer are also included within the scope of the present invention.

The ceramic layer may be formed by heating a powder phosphor at high pressure until the surface of the phosphor particles begin to soften and melt. The partially melted particles stick together to form a rigid agglomerate of particles. Unlike a thin film, which optically behaves as a single, large phosphor particle with no optical discontinuities, the ceramic layer behaves as tightly packed individual phosphor particles, such that there are small optical discontinuities at the interface between different phosphor particles. Thus, the ceramic layer is optically almost homogenous and have the same refractive index as the phosphor material forming the ceramic layer. Unlike a conformal phosphor layer or a phosphor layer disposed in a transparent material such as a resin, the ceramic layer generally requires no binder material (such as an organic resin or epoxy) other than the phosphor itself, such that there is very little space or material of a different refractive index between the individual phosphor particles. As a result, the ceramic layer is transparent or translucent, unlike a conformal phosphor layer.

Examples of phosphors that may be formed into the ceramic layer include aluminium garnet phosphors with the general formula

(Lu_{1-x-y-a-b}YₓGd_{y})₃(Al₁₋ₓGa_{z})₅O₁₂:CeₐPr_{b} wherein 0<x<1, 0<y<1, 0<z<0.1, 0<a<0.2 and 0<b<0.1, such as Lu₃Al₅O₁₂:Ce³⁺ and Y₃Al₅O₁₂:Ce³⁺ which emit light in the yellow-green range; and (Sr_{1-x-y}BaₓCa_{y})_{2-z}Si₅₋ₐAlₐN₈₋ₐOₐ:Eu_{z}²⁺ wherein 0<a<5, 0<x<1, 0<y<1, and 0<z<1 such as Sr₂Si₅N₈:Eu²⁺, which emit light in the red range. Suitable Y₃Al₅O₁₂:Ce³⁺ ceramic layers may be purchased from Baikowski International Corporation of Charlotte, N.C. Other green, yellow, and red emitting phosphors may also be suitable, including (Sr_{1-a-b}Ca_{b}Ba_{c})SiₓN_{y}O_{z}:Euₐ²⁺ (a=0.002-0.2, b=0.0-0.25, c=0.0-0.25, x=1.5-2.5, y=1.5-2.5, z=1.5-2.5) including, for example, SrSi₂N₂O₂:Eu²⁺; (Sr₁₋ᵤ₋ᵥ₋ₓMgᵤCaᵥBaₓ)(Ga_{2-y-z}Al_{y}In_{z}S₄):Eu²⁺ including, for example, SrGa₂S₄:Eu²⁺; Sr₁₋ₓBaₓSiO₄:Eu²⁺; and (Ca₁₋ₓSrₓ)S:Eu²⁺ wherein 0<x<1 including, for example, CaS:Eu²⁺ and SrS:Eu²⁺.

As stated above, the ceramic layer may be completely transparent (no scattering at all) or translucent. For this purpose, the ceramic body has a ceramic density of above 90%, and in particular at least 95% to 97%, in particular almost 100%. The ceramic layer may have crystallites with a grain size from the range of 1 μm to 100 μm inclusive. The grain size is an equivalent diameter of the crystallites of a microstructure of a ceramic. The grain size is preferably 10 μm to 50 μm. This grain size enables efficient luminescence conversion.

When the ceramic layer is translucent, it contains a limited amount of Mie-scattering in forward direction. This is achieved by inclusion of a small amount of small ‘foreign’ particles (different refractive index) or pores. Some scattering is also observed for ceramics made of materials with a non-cubic lattice structure. An alternative would be the incorporation of e.g. YAG:Ce³⁺ grains (phosphor particles) in a Al₂O₃ matrix.

Mie theory, also called Lorenz-Mie theory, is a complete mathematical-physical theory of the scattering of electromagnetic radiation by spherical particles. Mie scattering embraces all possible ratios of diameter to wavelength. It assumes an homogeneous, isotropic and optically linear material irradiated by an infinitely extending plane wave.

A preferred ceramic layer to be used in the present invention is a so-called LUMIRAMIC platelet, described in detail in US Patents having publication numbers 2004/0145308, and 2005/0269582, incorporated herein by reference. The absence of scattering, or the very limited amount of scattering in the ceramic layer is very advantageous because a better efficiency, and a good colour control can be obtained (1 μm variation of ˜100 μm is much smaller than 1 μm on 10 μm, i.e. the typical phosphor powder thickness).

The luminescent material (4) in the ceramic layer preferably comprises a phosphor, or a blend of phosphors. Examples of appropriate luminescent materials (4) are base materials such as aluminates, garnets or silicates, which are partly doped with a rare earth metal. For a blue emitting LED, the luminescent material (4) preferably comprises a yellow emitting phosphor, such as a (poly)crystalline cerium doped yttrium aluminium garnet (YAG:Ce³⁺ or Y₃Al₅O₁₂:Ce³⁺) or manganese doped zinc sulphide (ZnS:Mn²⁺). Alternatively, YAG:Ce³⁺ may be co-sintered with Al₂O₃ to yield a luminescent ceramic. The phosphors are preferably uniformly dispersed in the ceramic layer.

The scattering layer (5) may comprise e.g. epoxy or silicone. The scattering layer (5) may have different geometrical shapes, and functions as a bond, a so-called optic bond, between the radiation source and the ceramic layer.

The scattering particles (6) incorporated into the scattering layer (5) is preferably SiO₂-coated TiO₂-particles. The coating of the TiO₂-particles with SiO₂ is very advantageous, since the photocatalytically active TiO₂-surface is then shielded from the organic matrix, thus preventing rapid degradation of the matrix materials. Although SiO₂-coated TiO₂-particles are preferred, other particles with a high refractive index, e.g. ZrO₂, could also be used as scattering particles.

By using small scattering particles (6), i.e. tens of nanometres, the scattering will be Mie-type (forward scattering), not leading to a reduction of the system efficacy. Suitably, the particle size is less than 50 nm. The scattering particles (6) may be of any geometrical shape which is suitable to be incorporated in the scattering layer and which provides the desired scattering effect. The scattering particles (6) are preferably essentially uniformly dispersed in the scattering layer (5).

In a light-emitting device (1) according to the invention, the scattering layer (5) preferably covers essentially the whole upper surface of the radiation source (2), and the ceramic layer (3) preferably covers essentially the whole upper surface of the scattering layer (5).

The light-emitting device (1) according to the invention, combining ceramic plates and using scattering particles in the optic bond, provides a solution to a long-felt need of obtaining phosphor converted LEDs having a homogeneous light emission and a high efficiency.

A suitable procedure for manufacturing a light-emitting device according to the invention is described in the following non-limiting example.

### EXAMPLE

1 gram of SiO₂ coated TiO₂ nanoparticles is mixed with 5 grams of a silicone gel. A small amount of the material is applied onto the LED using dispensing. A LUMIRAMIC platelet is placed over the dispersion using a pick and place machine. After curing of the silicone gel, a dome is placed over the die and filled with a (clear) encapsulant. The thickness of the optical bond (i.e. the dispersion of SiO₂ coated TiO₂ nanoparticles in a silicone gel) can be controlled by the pick and place machine. Excess of material will flow off the die, filling the space below the LUMIRAMIC plate (amount controlled by the dispensed amount).

1. A light-emitting device, comprising:
a radiation source;
an inorganic layer comprising a ceramic material having a luminescent material dispersed therein; and
a scattering layer comprising a plurality of scattering particles and located between said radiation source and said inorganic layer.

2. A light-emitting device according to claim 1, wherein said scattering particles comprise SiO₂-coated TiO₂ particles.

3. A light-emitting device according to claim 1, wherein said scattering layer comprises a silicone material.

4. A light-emitting device according to claim 1, wherein said inorganic layer is transparent.

5. A light-emitting device 1) according to claim 1, wherein said inorganic layer is translucent.

6. A light-emitting device according to claim 5, wherein said ceramic material exhibits Mie-scattering.

7. A light-emitting device according to claim 1, wherein said inorganic layer comprises a self-supporting platelet.

8. A light-emitting device according to claim 1, wherein said radiation source is a LED emitting blue light.

9. A light-emitting device according to claim 1, wherein said luminescent material comprises a phosphor emitting yellow light.

10. A light-emitting device according to claim 9, wherein said phosphor is cerium doped yttrium aluminium garnet, or manganese doped zinc sulphide.

11. A light-emitting device according to claim 1, wherein said scattering layer binds said inorganic layer to said radiation source.

12. (canceled)

13. A light-emitting device according to claim 1, wherein said ceramic material has a ceramic density exceeding 90%.

14. A light-emitting device according to claim 1, wherein said inorganic layer is substantially homogenous and has a refractive index substantially matching a refractive index of the luminescent material.
